(19) United States
(12) Patent Application Publication
(10) Pub. No.: US 2012/0206133 A1
(43) Pub. Date: Aug. 16, 2012

(54) Resonant Electromagnetic Sensor

(76) Inventor: Kevin D. McGushion, Simi Valley, CA (US)

(21) Appl. No.: 13/396,378

(22) Filed: Feb. 14, 2012

Related U.S. Application Data
(60) Provisional application No. 61/442,742, filed on Feb. 14, 2011.

(51) Int. Cl. G01R 33/12

(52) U.S. Cl. 324/239

(57) ABSTRACT

The present device relates to a sensor capable of detecting changes in the electromagnetic field it generates when in proximity to either conductive or nonconductive materials. This occurs by way of oscillating a transmit coil with an electro motive force at a resonant frequency thus creating an electromagnetic field. The magnetic field passes through a target of either conductive or nonconductive material and is then intercepted by a receive coil which likewise oscillates at a resonant frequency, which when in proximity to the transmit coil and transmit coils resonant frequency produces an enhanced signal by way of the interaction of the respective resonant frequencies and receive coil output.

### RELATED APPLICATION DATA

This application claims the priority date of provisional application No. 61/442,742 filed on Feb. 14, 2011.

### BACKGROUND

The present device relates to a sensor capable of detecting changes in the electromagnetic field it generates when in proximity to either conductive or nonconductive materials.

There has been a persistent need to inspect both conductive and nonconductive items for consistency and for the presence of flaws with a single technology capable of overcoming deficiencies associated with traditional x-ray, eddy current, ultrasonic and other nondestructive inspection methods currently employed. The problem with x-ray has been the dangerous nature of the high energy electromagnetic wave and the hazards to biological organisms are well understood, given this and the need for elaborate shielding, x-ray can be very undesirable. Also, while x-ray is useful for detecting volumetric anomalies such as voids or the presence of foreign objects, flaws such as cracks where the adjoining faces of the cracks may be in intimate contact and having no appreciable volume, are very difficult to detect.

Standard eddy current inspection is useful in detecting discontinuities in metal and other conductive materials, but do not work well when inspecting nonconductive materials. The inability to inspect nonconductive materials has limited eddy current applications. Eddy current inspection may also employ design features which allow the effects of signal output due to changes in liftoff (the distance between the sensor and the item) to be inspected to be mitigated. These design features are permanent and may not be changed on the fly during inspection, thus limiting its ability to instantaneously determine liftoff.

Ultrasonic inspection can be difficult to employ, given the need to provide a coupling fluid or gel to transmit the ultrasonic frequency from a transducer to a target being inspected. It is often impractical to use such coupling fluids and gels on many structures as well as completed structures such as can be expected in the air frame of a finished aircraft, especially when constructed of composite. Also, it is not possible to use ultrasonic inspection technologies when there is an air gap separating otherwise inspectable walls, as air lacks the necessary transmissive qualities associated with a coupling fluid.

Accordingly, there is a need for a sensor which does not produce harmful radiation, which can inspect conductors and nonconductors alike and can inspect through walls of various materials and air gap transitions. Such a sensor should be very compact to allow easy access to confined spaces and should also allow for inspection of small features and anomalies which may be critical to the performance of the item or system being inspected. The sensor should provide an output that has signal variation relative to varying features or anomalies of a target and which may be located in the item being inspected. The sensor should have the ability to control for variables such as liftoff or material changes without the need to make permanent physical changes to the sensor.

### SUMMARY

The above mentioned need is met by the present resonant electromagnetic sensor, which provides for an enhanced signal output by utilizing a transmit coil which resonates at a fixed or series of resonant frequencies. When an electro motive force (EMF) at resonant frequency or frequencies is induced to the transmit coil, it generates an electromagnetic field which oscillates relative to the frequency applied. This electromagnetic field passes through a target of either conductive or nonconductive material; and is then intercepted by a receive coil which also resonates at a frequency or series of frequencies in strategic proximity to the resonant frequency or frequencies of the transmit coil. The receive coil, by way of Lenz's Law converts the intercepted oscillating magnetic field and converts it to a signal which can be analyzed to reveal subtle and gross changes in the material being inspected. The proximity of the frequencies of the transmit and receive coils is meant to maximize sensor output by way of high ‘Q’ or quality factor and of high output signal which occurs when the transmit and receive coils have been tuned and brought into proximity to one another.

The present sensor also provides frequencies at which the effects of liftoff and/or target material change may be mitigated if the transmit and receive coils have been appropriately tuned. Because of its high ‘Q’ and output signal, the present sensor is very sensitive to not only the subtle changes that may exist in a target of conductive material, but nonconductive material as well, so that it may scan from one type of material to the next without the need for sensor changes. Because of its unique “tuning” ability by way of adjusting resonant frequencies of transmit and receive coils, the present sensor may neglect the effects of liftoff and or changing materials under the sensor in order to generate a more complete image of the material being inspected. The present sensor is also capable of scanning through multiple walls of materials, with air and other materials at the transition boundary between the walls, and resolve characteristics not only of the intermediate walls but of the wall on the far side as well.

### BRIEF DESCRIPTION OF THE SEVERAL VIEWS OF THE DRAWINGS

FIG. 1 is a perspective view of the resonant electromagnetic sensor constructed in accordance with this specification;

FIG. 2 is an orthographic end view of the sensor;

FIG. 3 is an orthographic side view of the sensor;

FIG. 4 is a perspective view of the sensor with a target material positioned in proximal to the sensor;

FIG. 5 is a schematic of transmit coil;

FIG. 6 is a frequency response graph of the transmit coil;

FIG. 7 is a schematic of the transmit coil and receive coil;

FIG. 8 is a frequency response graph of the transmit and receive coil;

FIG. 9 is a frequency response graph showing sympathetic resonance;

FIG. 10 is a schematic of the transmit and receive coils where the transmit capacitance is variable;

FIG. 11 is a schematic of the transmit and receive coils where the receive capacitance is variable;

FIG. 12 is a schematic of the transmit and receive coils where both receive and transmit capacitance are variable;

FIG. 13 is a frequency response graph showing an air gap control frequency;

FIG. 14 is a frequency response graph showing a wall control frequency; and

FIG. 15 is a schematic showing rectification and amplification of the receive coil output.

LISTING OF REFERENCE NUMERALS of
FIRST-PREFERRED EMBODIMENT

| | |
|---|---|
| Sensor Assembly | 20 |
| First Lead of the Transmit Coil | 22 |
| First Lead of the Receive Coil | 24 |
| Receive Coil | 26 |
| Transmit Coil | 28 |
| Core | 30 |
| Second Lead of the Receive Coil | 32 |
| Second Lead of the Transmit Coil | 34 |
| Oscillating Magnetic Field | 36 |
| Discontinuity in Target Material | 38 |
| Target Material | 40 |
| Transmit Coil Circuit | 41 |
| Source of Oscillating EMF | 42 |
| Receive Coil Circuit | 43 |
| Transmit Coil Capacitor | 44 |
| Transmit Coil Resistor | 46 |
| Resonant Peak | 48 |
| Voltage Level at −3 dB | 50 |
| Upslope Side of Curve | 52 |
| Frequency 1 | 54 |
| Resonant Frequency | 56 |
| Frequency 2 | 58 |
| Bandwidth | 59 |
| Downslope Side of Curve | 60 |
| Peak Voltage at Resonant Frequency | 62 |
| Receive Coil Resistor | 64 |
| Signal Monitoring and/or Conditioning Device | 66 |
| Receive Coil Capacitor | 68 |
| Transmit Coil Resonant Peak | 70 |
| Trough | 72 |
| Receive Coil Resonant Peak | 74 |
| Transmit Coil Variable Capacitor | 76 |
| Transmit Coil First Resonant Peak | 78 |
| Transmit Coil Second Resonant Peak | 80 |
| Sympathetic Resonant Peak | 82 |
| Transmit Coil Fourth Resonant Peak | 84 |
| Transmit Coil Fifth Resonant Peak | 88 |
| Transmit Coil Sixth Resonant Peak | 90 |
| Receive Coil Variable Capacitor | 92 |
| Wall Control Frequency | 94 |
| Resonant Frequency Shift for Air Gap | 96 |
| Air Gap Control Frequency | 98 |
| Resonant Frequency Shift for Wall | 100 |
| Rectifier Portion of Circuit | 102 |
| Amplifier First Stage | 104 |
| Amplifier Second Stage | 106 |
| Signal Output | 108 |
| Offset Input | 110 |
| Gain Resistor | 112 |

### DESCRIPTION OF THE PREFERRED EMBODIMENTS

Referring to the drawings wherein identical reference numerals denote the same elements throughout the various views. The following description of the resonant electromagnetic sensor is the preferred embodiment when said system is reduced to practice however, it is not intended to be the only embodiment as features and practices may be altered while still remaining within the intent and scope of this specification.

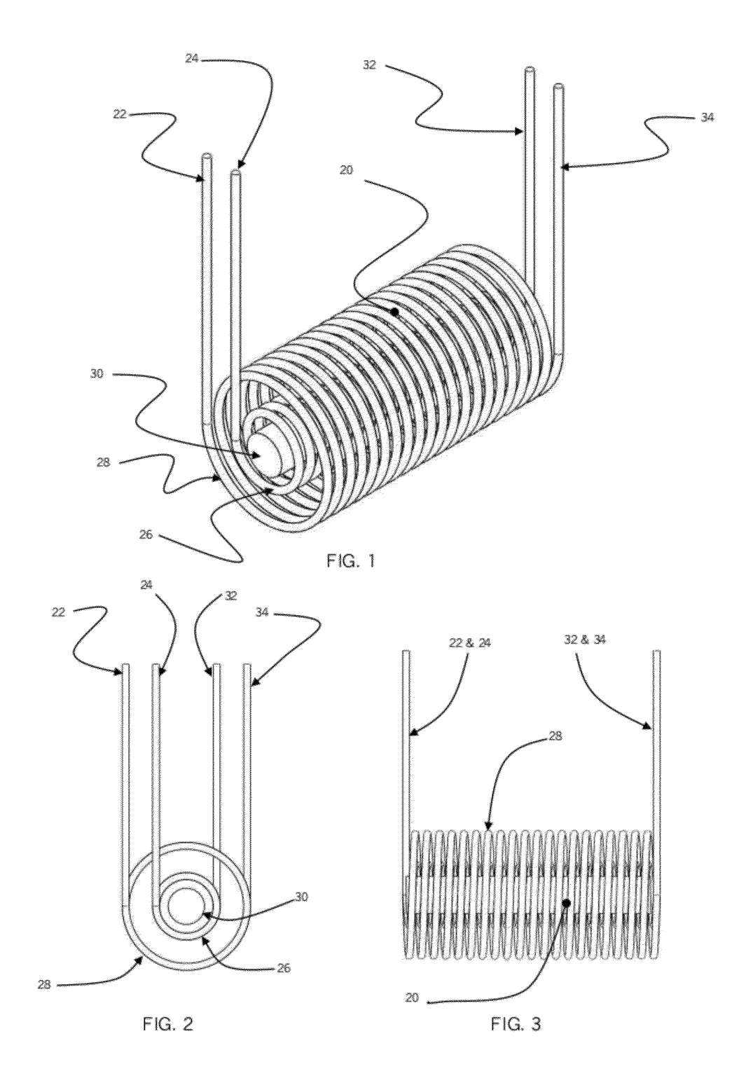

FIG. 1 is a preferred embodiment of the sensor assembly 20, comprised of a transmit coil 28 and a receive coil 26 concentrically arranged and with the receive coil 26 within the transmit coil 28. Within the receive coil is an optional core 30 made of material with high magnetic permeability and suitable for concentrating a magnetic field. This core serves to direct a greater amount of magnetic field to be generated by the transmit coil 28 into the area within the receive coil 26 so as to provide greater magnetic field to the receive coil 26. This magnetic field once concentrated within the receive coil 26 by way of the core 30 can be converted to an oscillating electromotive force or EMF in accordance with Lenz's Law. Also shown in this figure are the leads of the coils. The first lead of the transmit coil 22 and the second lead of the transmit coil 34 are to be energized with an oscillating electromotive force or EMF. The first lead of the receive coil 24 and the second lead of the receive coil 32 provide a signal output by converting an induced magnetic field to an EMF.

FIG. 2 is an end view of the sensor assembly showing the transmit coil 28 wound outside and concentric to the receive coil 26. There is a gap shown between the two coils as illustrated, but this gap can be very small or the two coils may be in contact with one another. There may even be materials used to separate the coils or a bobbin used to wind the transmit coil, which then becomes interposed between the two coils. Also visible in this figure is the core 30 of high permeability material meant to concentrate the magnetic field to be generated by the transmit coil 28.

FIG. 3 shows the side view of the sensor and how the various components may be arranged within it. While the coils and the core are all of equal length, these lengths may be varied for ease of construction or to enhance performance. Also the number of turns on the transmit 28 and receive coil 26 may vary greatly. The number of turns selected for each will depend on several factors, such as the desired operating frequency, the desired energy transfer, and the desired amount of parasitic characteristics, or characteristics such as resistance, capacitance and inductance inherent in the winding itself.

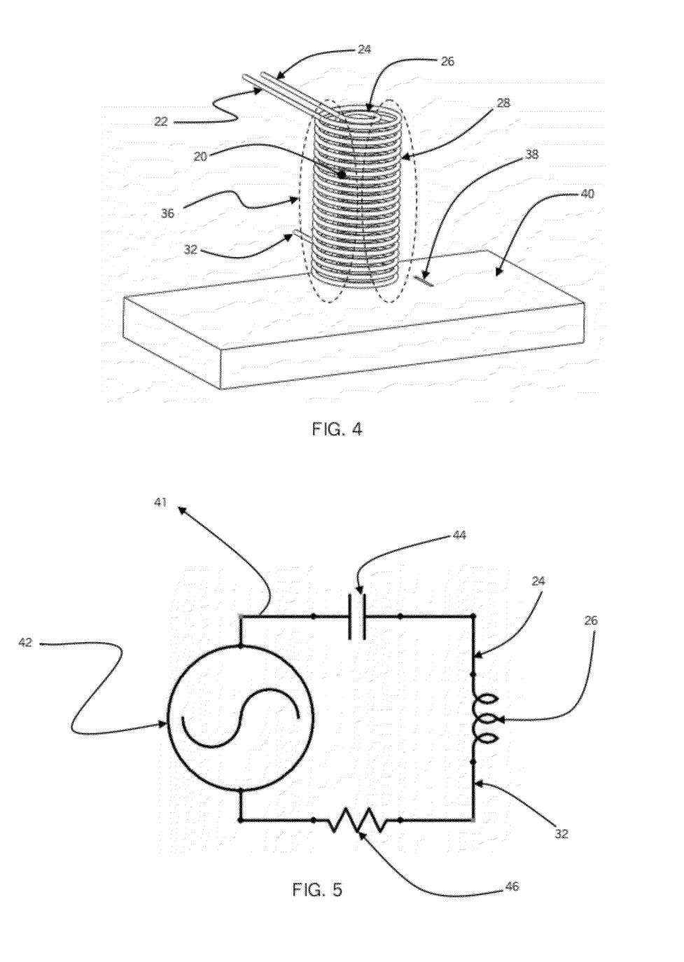

FIG. 4 shows the oscillating magnetic field 36 which has been generated by providing and oscillating EMF to the transmit coil 28. This magnetic field oscillates at a frequency which matches the oscillation applied to the leads 22 and 34 of the transmit coil 28. Placed in front of the sensor assembly 20, or in sensing proximity, is the target material 40, which may be made of conductive or nonconductive matter or a compound of materials. This matter or compound may be solid, liquid or gas as the sensor assembly 20 is capable of discerning characteristics for all of these states. For the sake of this explanation however, we will assume that this target material 40 is solid. Within or on the target material 40 is a discontinuity 38, which may be a flaw or a desired feature of either the same material of the target or different material. This discontinuity may be present on the surface closest to the sensor, within the target or on the side of the target farthest from the sensor assembly 20.

FIG. 5 is a schematic of the basic transmit coil circuit 41 and is shown to better understand the details of the sensor assembly 20. In this schematic, the source of oscillating EMF 42 can be seen as well as a classic LRC circuit taught in basic electronics. In this circuit there is a resistor 46, an inductor or transmit coil 26 and a capacitor 44. Transmit coil 26 having leads 24 and 32 connecting it to the circuit. It is well understood that in such a circuit the resonant frequency can be known by the formula f=1/2π(LC)^{1/2}. Where f is the resonant frequency of the transmit coil circuit 41 and L is the inductance of the transmit coil 28 and C is the transmit coil capacitor 44. It is important to note that while there is a resistor and capacitor shown, a contributing resistance and capacitance in the circuit can also be by way parasitic resistance and capacitance in the transmit coil 26. Also, while the resistance, inductance and capacitance in this circuit is shown in series, one or more of these elements could be in parallel arrangement. It is also useful to recognize that resonance is reached when inductive reactance X_{L} is equal to and opposite capacitive reactance X_{C} and since XL=2πfL and XC=½πfC, it is easy to see how the formula for resonant frequency is derived.

While resistance is not shown in these formulas, it is an important component in the overall amplitude of the magnetic field 36 being created by the transmit coil 28. Altering either capacitance by way of changing the transmit coil capacitor 44 or the inductance of the transmit coil 28 has a dramatic effect on the resonant frequency of the circuit. Although it is not shown, inductance can be varied by adding an additional inductor or a variable inductor. However, the preferred embodiment is to vary the transmit coil capacitor 44 to tune resonant frequency as you might a radio receiver.

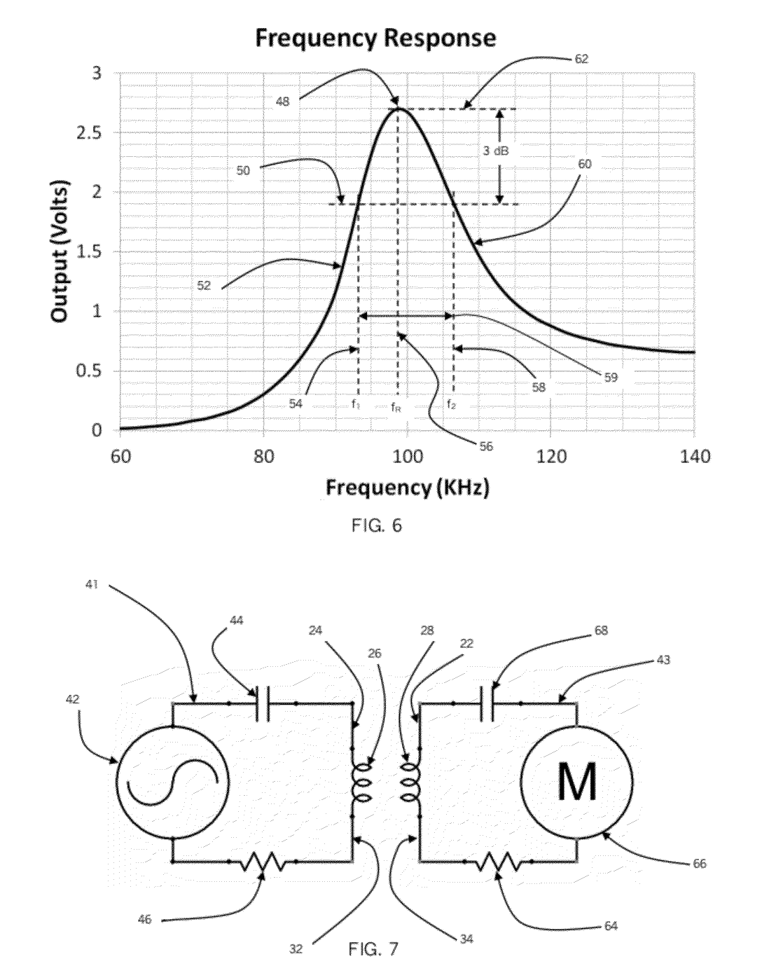

FIG. 6 shows the frequency response of a simple LRC circuit as with the transmit coil circuit 41 where there is a clear resonant peak 48 where X_{L} is equal to X_{C}. It is clear that at frequencies below and above resonant frequency 56 the reactance increases and efficiency drops as is shown by the upslope side of the curve 52 as well as the downslope side of the curve 60. An important way to measure the quality of a resonating circuit or ‘Q’ is to divide the resonant frequency 56 by the bandwidth 59. Bandwidth 59 is given by measuring 3 dB down from the peak voltage at resonant frequency 62 to arrive at the voltage level at −3 dB 50. At that voltage level a horizontal line can be drawn 50 and where it intersects the frequency response curve two vertical lines can be drawn 54 and 58 where 54 is frequency 1 and 58 is frequency 2. By subtracting frequency 2, 58 from frequency 1, 54 bandwidth 59 can be known, or bandwidth=f2−f1. To calculate ‘Q’ the resonant frequency 56 is divided by the bandwidth 59. ‘Q’ will be used later in describing preferred operating frequencies of the sensor assembly 20.

FIG. 7 shows a schematic of the transmit coil circuit 41 and the receive coil circuit 43. The receive coil 26, as mentioned, is collocated concentrically with and inside the transmit coil 28. Its purpose is to intercept the magnetic field 36 generated by the transmit coil 28 after having passed through the target material 40. It is preferred not to simply intercept the magnetic field 36, but rather to first tune the resonant frequency of the receive coil 26 to in some cases exactly match or have parity with the resonant frequency 56 of the transmit coil 26 and in other cases to be close to, or have approximate parity to the resonant frequency 56 of the transmit coil 26. This is done by again tuning receive coil circuit 43 by varying either inductance or the receive coil capacitor 68. In the preferred embodiment it is desirable to adjust or tune capacitance by varying the receive coil capacitor 68. As before variations in the receive coil resistor 64 serves to affect amplitude of the signal output. By tuning both the transmit circuit 41 and the receive coil circuit 43 to either parity or approximate parity, depending on the particulars of the circuit, an enhanced transmission of power can be realized from the transmit coil circuit 41 to the receive coil circuit 43.

The energy transferred to the receive coil circuit 43 is monitored with signal monitoring and or conditioning device 66. This device may monitor the oscillating signal from the receive coil circuit with a display, commonly referred to as an impedance plane display, where impedance is given on an oscilloscope type device, where one axis of the display represents resistance of the circuit and the other axis represents inductive reactance. The preferred method of conditioning and monitoring in this embodiment which will be explained in FIG. 15 is rectification and then amplification of the DC signal. It is this preferred method that was used in the collecting of data for the frequency response curves in this specification.

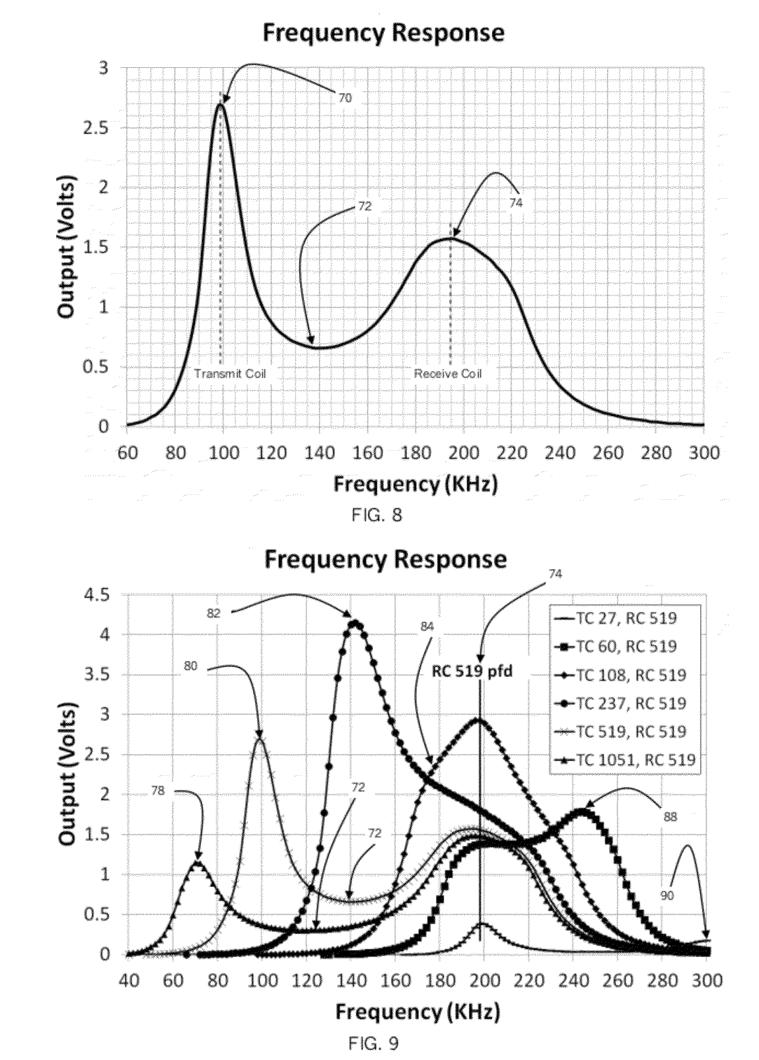

FIG. 8 shows a frequency response of the circuit in FIG. 7 where the transmit coil circuit 41 has a resonant peak 70 which is at approximately 99 KHz and the receive coil circuit 43 has a receive coil resonant peak 74 which is approximately at 195 KHZ. While each of these peaks are at resonance and each is capable of detecting variations in material 40, this circuit has not been optimized. It can be seen that there is a trough 72 between the transmit coil resonant peak 70 and the receive coil resonant peak 74. This trough 72 is indicative of poor energy transfer from transmit coil circuit 41 and receive coil circuit 43 by way of transmit coil 26 and receive coil 28. It is desirable to minimize this trough 72 to enhance performance of the circuit of FIG. 7 and of the sensor assembly 20. This trough 72 can be minimized by proper tuning of the circuit of FIG. 7.

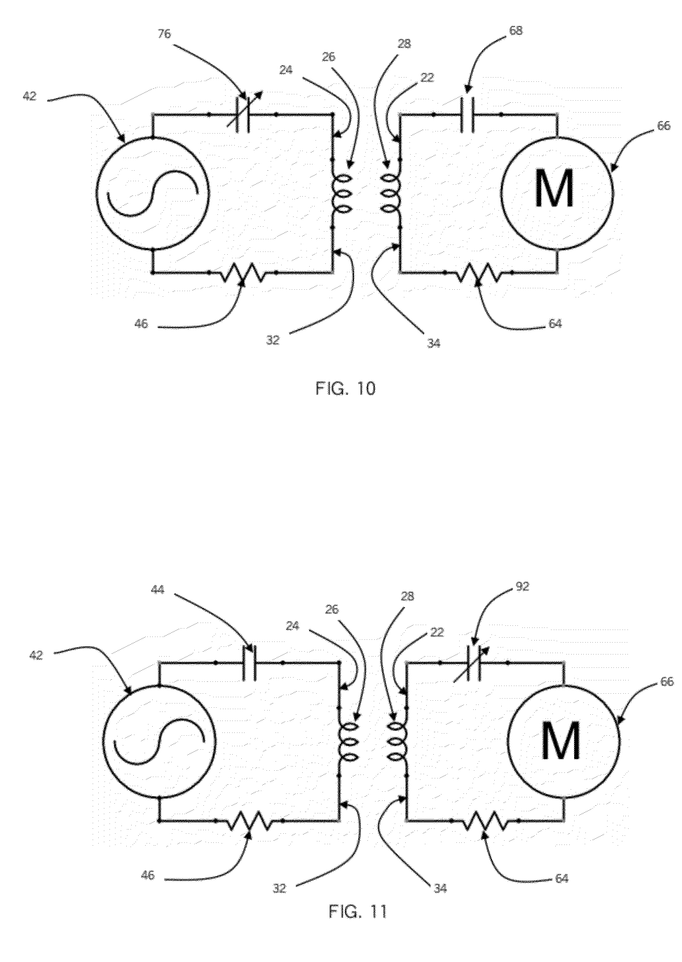

FIG. 9 shows the frequency response of multiple variations of the circuit of FIG. 7, where the receive coil capacitor 68 has been set and held at 519 pfd (pico farads) giving a receive coil resonant peak 74 of about 195 KHz. It can be seen that as the transmit coil capacitor 44 of the transmit coil circuit 41 is changed to different values there is a dramatic effect on frequency response. It can be seen that a transmit coil first resonant peak 78 with a transmit coil capacitor 44 of 1052 pfd is far removed from the receive coil resonant peak 74 and transfers a low amount of energy from the transmit coil circuit 41 to the receive coil circuit 43 and that the trough 72 is quite wide. The transmit coil second resonant peak 80 has greatly improved in amplitude by using a transmit coil capacitor 44 of 519 pfd. This has brought its resonant peak 80 closer to the receive coil resonant peak 74 and in so doing has boosted energy transfer by improving “sympathetic resonance”, where the resonant frequency of the transmit coil is either in parity with or in approximate parity to the resonant frequency of the receive coil such that output is increased beyond the output of the constituent resonant peaks. Maximum output of this particular circuit of FIG. 7 reaches its maximum when the transmit coil capacitor 44 is set at 237 pfd, yielding sympathetic resonant peak 82. At this frequency of about 142 KHz, the circuit will be most sensitive to changes in target material 40 and will be most able to detect variations such as discontinuities in target material 38. In this case, this peak occurred at an approximate parity frequency which does not match the receive coil resonant peak 74. This is due to a wide variety of reasons from the construction of the sensor assembly 20 to the particular tuning of the circuit of FIG. 7. Depending on construction and tuning, the sympathetic resonant peak could be at frequencies lower than, greater than or equal to the receive coil resonant peak 74. Transmit coil fourth, fifth and sixth resonant peaks 84, 88 and 90, respectively, occur at different frequencies but are not optimized.

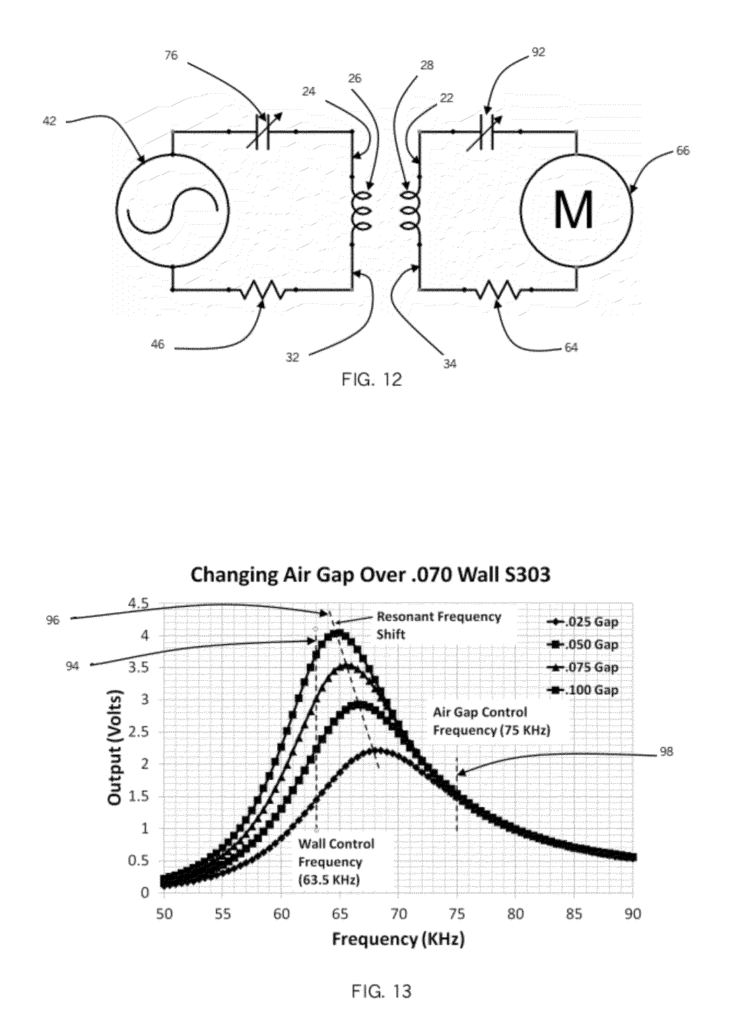

FIGS. 10, 11 and 12 show the addition of variable capacitors to either the transmit coil circuit 41 or the receive coil circuit 43 or both. FIG. 10 shows transmit coil capacitor 44 being replace with transmit coil variable capacitor 76. FIG. 11 shows receive coil capacitor 68 being replaced by receive coil variable capacitor 92 and FIG. 12 shows both the transmit coil capacitor 44 and the receive coil capacitor 68 being replace by transmit coil variable capacitor 76 and receive coil variable capacitor 92 respectively. These aforementioned variable capacitors may be manually variable or variable by electronic signal. The purpose of these variable capacitors is to allow rapid switching to other desired resonant peaks or sympathetic resonant peaks in order to more thoroughly inspect the target material 40.

FIG. 13 shows a circuit tuned to a resonant frequency which may or may not be the sympathetic resonant frequency, where desirable characteristics other than maximum power transfer or maximum output occur. This tuning may be achieved by adjusting one or more variable capacitors such as in the circuits of FIG. 10, 11 or 12.

It is often a desirable feature of a sensor to be able to control for variables such as liftoff, the gap or distance from the sensor assembly 20 to the target material 40, or changes in material configuration such as the wall thickness of that material. FIG. 13 shows how the control of gap may be accomplished by monitoring the output of the circuit at the air gap control frequency 98 of 75 KHz as opposed to the resonant peak. In doing this, it can be seen that the effects of gap are greatly mitigated relative to other frequencies.

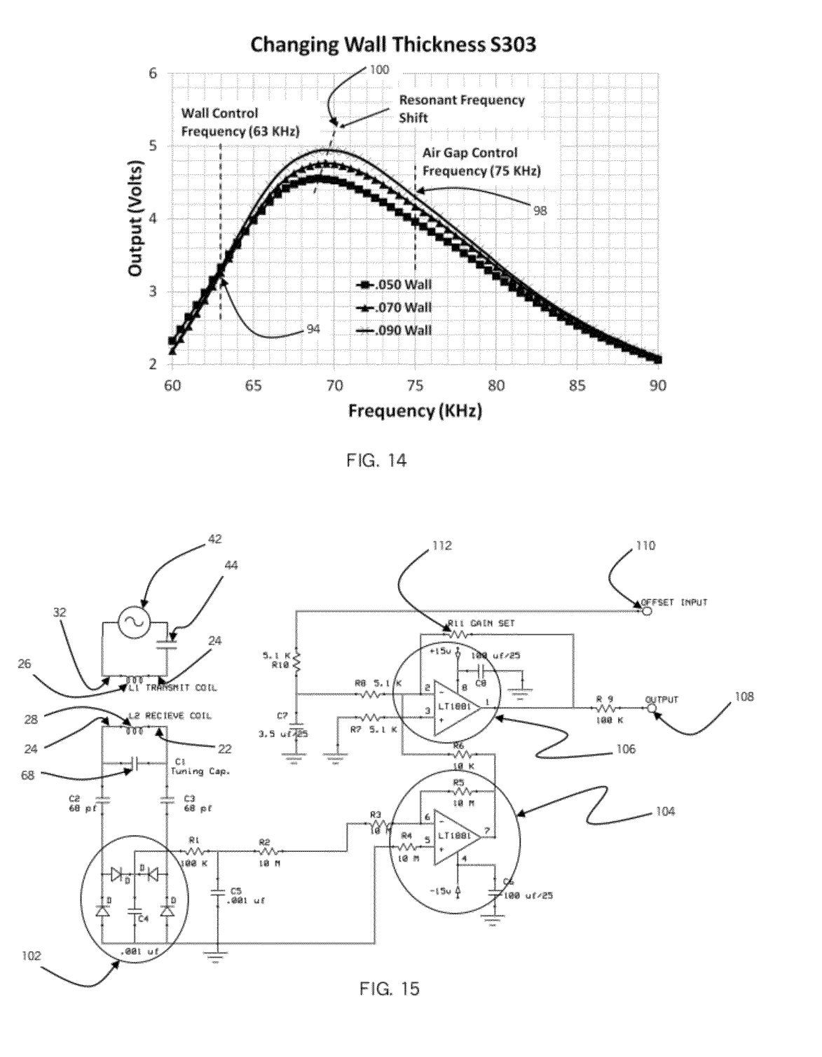

The same circuit is shown in FIG. 14, but instead of varying gap, the wall thickness of the material is varied. It can be seen that the air gap control frequency 98, which mitigates changes in gap, is sensitive to changes in wall. This means that even though there are changes in the distance from the sensor to the target, those changes are mitigated while the effects of varying wall can be clearly seen.

Similarly, at the wall control frequency 94 of 63 KHz, as wall is varied the signal is mitigated, but as gap is varied, the signal output changes appreciably. In this manner the sensor assembly 20 may be tuned to control variables and or tuned to provide maximum output and frequencies may be switched as desired to achieve maximum signal or mitigated signal. While the control signals for wall and gap have been shown, other control frequencies exist to mitigate change in material or change in temperature which are found by similar tuning methods.

Further studying the frequency response curve of FIG. 13, it can be appreciated that the compression of curves at and about the air gap control frequency 98 and the subsequent expansion of curves at the wall control frequency 94 occurs as a result of a resonant frequency shift for air gap 96. It can be seen that as air gap increase the signal amplitude rises while the resonant frequencies shift lower. This is true of this particular tuning setting and the phenomena may be reversed if tuned differently where the resonant frequency shift for air gap may be to higher frequencies, causing a reversal in the compression and expansion of the curves and or causing a reduction in signal due to increased air gap.

Conversely, in FIG. 14 as wall thickness changes the resonant frequency shift for wall 100 is to higher frequencies as wall thickness increases and signal increases as wall increases. This causes a compression of the curves at the wall control frequency 94 and an expansion of the curve at the air gap control frequency 98. Again, depending on tuning, these compression and expansion areas may be reversed and signal may diminish relative to wall.

FIG. 15 shows a preferred embodiment of the signal monitoring and or conditioning device 66, where the output of the receive coil circuit 43 is fed into a rectifier circuit 102 to convert the oscillating signal to a DC or direct current output. The DC signal is then fed into an amplifier first stage 104 where the signal is amplified. The amplified signal is then sent to the amplifier second stage 106, where additional amplification may be accomplished by setting or adjusting gain resistor 112. Often, there is a computer which will receive the output 108 of the signal monitoring and or conditioning device 66 and FIG. 15, as many computers can tolerate a relatively narrow voltage input of perhaps +/−10 volts. Should the signal become too large due to amplification, resonant tuning or high voltage being delivered by source of oscillating EMF 42, an offset input 110 may be applied. In so doing the output voltage is shifted to a lower voltage which can be received by the computer while preserving any effects that may have come about by monitoring variations in target material 40.

What is claimed is:

1. A sensor capable of detecting changes in a target material comprising:
at least two coils and at least one transmit coil and at least one receive coil;
the transmit coil having been tuned to a desired resonant frequency or frequencies is brought to that frequency by inducing an oscillating electromotive force thus creating an oscillating magnetic field also at the resonant frequency extending from the transmit coil, such that the field is allowed to propagate into a target material;
the oscillating magnetic field then being intercepted by a receive coil with a resonant frequency which is in proximity to the resonant frequency of the transmit coil such that the output signal of the receive coil is improved for desired detection of features, flaws, and conditions of the target material.

2. The sensor of claim 1 having been tuned to additionally provide a frequency or frequencies which mitigate or enhance the effects of changing distance from the sensor to the target.

3. The sensor of claim 1 having been tuned to additionally provide a frequency or frequencies which mitigate or enhance the effects of material changes.

4. The sensor of claim 1 having been tuned to additionally provide a frequency or frequencies which mitigate or enhance the effects of wall thickness changes.

5. The sensor of claim 1 having been tuned to additionally provide a frequency or frequencies which mitigate or enhance the effects of temperature.

6. The sensor of claim 1 where the resonant frequency is tuned by altering the capacitance and or inductance and or resistance of either or both the transmit and the receive coil.

7. The sensor of claim 1 where the resonant frequency is tuned by automatically altering the capacitance and or inductance and or resistance of either the transmit and or the receive coil.

8. A sensor capable of detecting changes in various target materials comprising
at least 2 coils and at least one transmit coil and one receive coil;
the transmit coil having been tuned to a desired resonant frequency or frequencies is brought to that frequency by inducing an oscillating electromotive force, thus creating an oscillating magnetic field also at the resonant frequency extending from the transmit coil, such that the field is allowed to propagate into a target material;
the oscillating magnetic field then being intercepted by a receive coil with a resonant frequency which is in proximity to the resonant frequency of the transmit coil such that the output signal of the receive coil is improved for desired detection of features, flaws and conditions of the target;
the sensor also incorporating a core of material suitable to selectively enhance and concentrate the oscillating magnetic field being generated by the transmit coil and positioned to derive maximum out of the receive coil.

9. The sensor of claim 8 having been tuned to additionally provide a frequency or frequencies which mitigate or enhance the effects of changing distance from the sensor to the target.

10. The sensor of claim 8 having been tuned to additionally provide a frequency or frequencies which mitigate or enhance the effects of material changes.

11. The sensor of claim 8 having been tuned to additionally provide a frequency or frequencies which mitigate or enhance the effects of wall thickness changes.

12. The sensor of claim 8 having been tuned to additionally provide a frequency or frequencies which mitigate or enhance the effects of temperature.

13. The sensor of claim 8 where the resonant frequency is tuned by altering the capacitance and or inductance and or resistance of either the transmit and or the receive coil.

14. A sensor of claim 1 where the resonant frequency is tuned by automatically altering the capacitance and or inductance and or resistance of either the transmit and or the receive coil.
